(19) United States
(12) Patent Application Publication
(10) Pub. No.: US 2007/0148875 A1
(43) Pub. Date: Jun. 28, 2007

(54) Common drain dual semiconductor chip scale package and method of fabricating same

(76) Inventors: Ming Sun, Sunnyvale, CA (US); Demei Gong, Shanghai (CN); Yueh Se Ho, Sunnyvale, CA (US)

Correspondence Address: FORTUNE LAW GROUP LLP, 100 CENTURY CENTER COURT, SUITE 315, SAN JOSE, CA, 95112, US

(21) Appl. No.: 11/316,692

(22) Filed: Dec. 22, 2005

(51) Int. Cl. H01L 21/336

(52) U.S. Cl. 438/270

(57) ABSTRACT

A common drain dual MOSFET chip scale package and a method of fabricating same are provided. The method of fabricating a plurality of common drain dual MOSFET chip scale packages includes the steps of providing a wafer having a plurality of common drain dual MOSFET devices disposed thereon, insulating a back drain metal surface of the wafer, under bump metallizing ball grid array pads on each of the common drain dual MOSFET devices, stenciling a solder mask to the wafer to expose the ball grid array pads, reflowing solder paste or pre-formed solder balls to form ball grid arrays of solder bumps, and dicing the wafer into the plurality of chip scale packages

### FIELD OF THE INVENTION

The present invention relates generally to power semiconductor packaging and more particularly to a common drain dual MOSFET chip scale package and method of fabricating same.

### BACKGROUND OF THE INVENTION

With the increased use of mobile devices such as cellular telecommunication products, portable digital assistants, and tablet PCs, the size, weight and cost of individual electronic components and devices are factors critical to a successful design. For example, battery pack protection for such devices may require a printed circuit board (PCB) incorporating a few discrete chips occupying a small land pattern.

One such prior art battery protection circuit board is disclosed in U.S. Patent Application Publication No. US 2004/0256738 A1 entitled “Battery Protection Circuit with Integrated Passive Components”. In order to achieve space conservation and efficiency, the disclosed PCB, which carries the active devices such a charge MOSFET and a discharge MOSFET connected in a common drain configuration, and the control IC for controlling the devices, has passive elements embedded in the body of the PCB. Interconnections to the surface mounted devices and the embedded passive element are made by suitable conductive vias and the like. The charge MOSFET and the discharge MOSFET define a bidirectional MOSFET chip scale package.

Chip scale packaging (CSP) is a wafer level packaging process which reduces the size of package structures to die-sized packages. In CSP as applied to an integrated circuit (IC), peripheral pads of the integrated circuit are connected to I/O solder balls by redistribution layer routing. These conductive I/O solder balls or bumps enable connection of the IC to higher level circuit structures such as PCBs by flip chip or tape automated bonding attachment.

Consistent with the need to reduce the size, weight and cost of individual electronic components including the common drain dual MOSFET chips package, there is a need in the art for this kind of the device package having a small footprint. There is a further need for a common drain dual MOSFET device package that has a low profile and good thermal dissipation. There is also a need for a common drain dual MOSFET package that is light weight. There is also a need for a common drain dual MOSFET package having low or no inductance. There is a further need for a common drain dual MOSFET package having low Rds(on). There also a need for a low cost process for making such a common drain dual MOSFET package.

### SUMMARY OF THE INVENTION

The present inventors have discovered and developed a novel wafer level process for fabricating a common drain dual MOSFET chip scale package having a common drain configuration which addresses the needs in the art. The process includes a step in which a back drain metal surface of the wafer is insulated with a dielectric material coating. The dielectric material coating provides protection to the back drain metal surface from subsequent processes including ball grid array bumping. The coating further adds mechanical strength of the wafer which advantageously provides increased throughput and yield in the fabrication of the common drain dual MOSFET chip scale packages.

In accordance with one aspect of the invention, a method of fabricating a plurality of common drain dual MOSFET chip scale packages includes the steps of providing a wafer having a plurality of common drain dual MOSFET devices disposed thereon, insulating a back drain metal surface of the wafer, under bump metallizing ball grid array pads on each of the common drain dual MOSFET devices, stenciling a solder mask to the wafer to expose the ball grid array pads, reflowing solder paste or pre-formed solder balls to form ball grid arrays of solder bumps, and dicing the wafer into the plurality of chip scale packages.

In accordance with another aspect of the invention, a common drain dual MOSFET chip scale package includes an insulating layer, the insulating layer being disposed adjacent a back drain metal surface of the dual MOSFET chip scale package.

There has been outlined, rather broadly, the more important features of the invention in order that the detailed description thereof that follows may be better understood, and in order that the present contribution to the art may be better appreciated. There are, of course, additional features of the invention that will be described below and which will form the subject matter of the claims appended herein.

In this respect, before explaining at least one embodiment of the invention in detail, it is to be understood that the invention is not limited in its application to the details of functional components and to the arrangements of these components set forth in the following description or illustrated in the drawings. The invention is capable of other embodiments and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other methods and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

The present disclosure may be better understood and its numerous features and advantages made apparent to those skilled in the art by referencing the accompanying drawings.

FIG. 1 is a flow chart of a fabrication process in accordance with the invention;

FIG. 1A is a diagrammatic representation of the fabrication process of FIG. 1 in accordance with the invention;

FIG. 2 is a schematic representation of a tape automated bonding attachment process in accordance with the invention; and

FIG. 3A is a schematic representation showing a board layout without molding and under fill and FIG. 3 B is a schematic representation showing an optional under fill in accordance with the invention.

### DETAILED DESCRIPTION OF THE INVENTION

The present invention discloses a wafer level method of fabricating a plurality of common drain dual MOSFET chip scale packages. The method advantageously provides for a process whereby common drain dual MOSFET chip scale packages may be formed from thin wafers including wafers of 7 to 8 mil thicknesses. Problems encountered in prior art processes including yield loss due to wafer warping are overcome by the novel process of the invention.

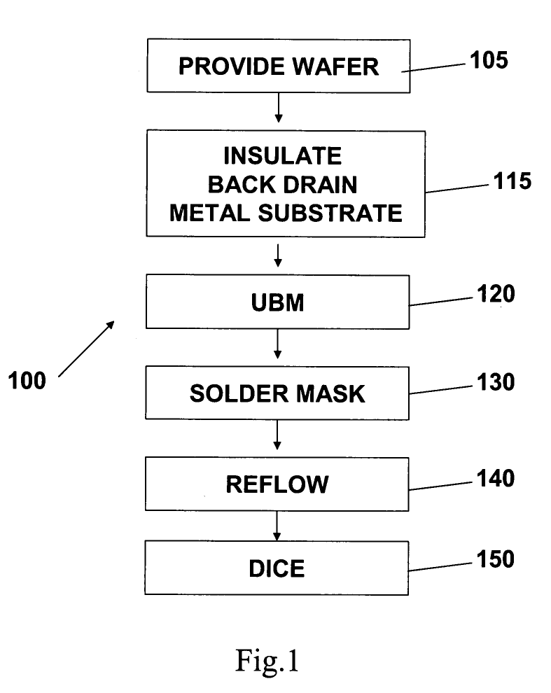

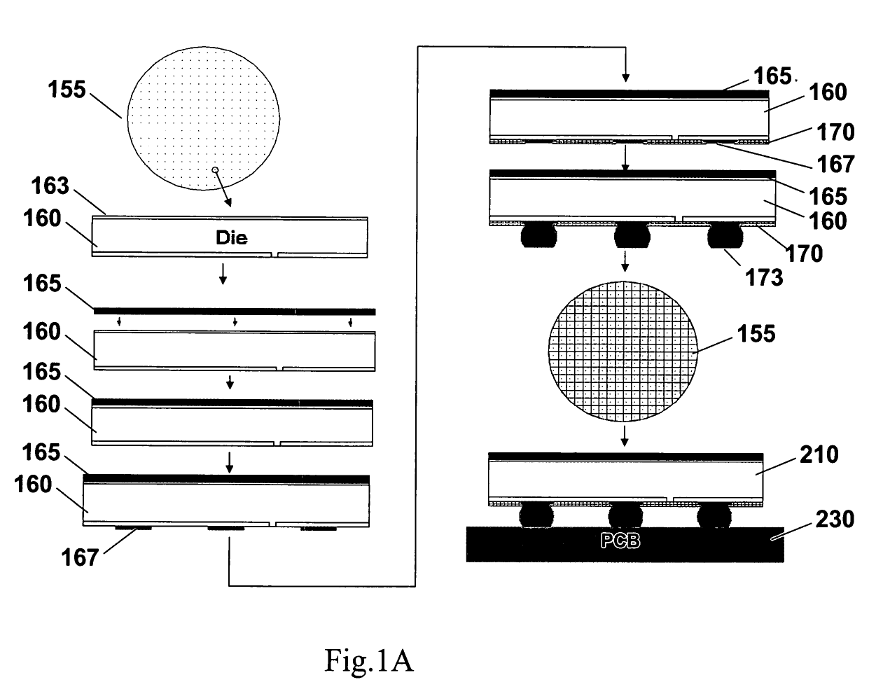

With reference to FIG. 1, a method of fabricating a common drain dual MOSFET generally designated 100 includes a first step 105 in which a wafer having a plurality of common drain dual MOSFET devices disposed thereon is provided. In a step 115 a back drain metal surface of the wafer is insulated. The back drain metal surface may be insulated with a cured dielectric material coating. The cured dielectric material coating provides protection to the back drain metal surface from subsequent processes including under bump metallization and ball grid array bumping. The coating further adds mechanical strength of the wafer which advantageously provides increased throughput in the fabrication of the common drain dual MOSFET chip scale packages

An under bump metallization (UBM) step 120 may include a Ni/Au metallization process as described in commonly assigned U.S. patent application Ser. No. 11/242,625, filed on Sep. 30, 2004 and entitled “Wafer-Level Method for Metallizing Source, Gate and Drain Contact Areas of a Semiconductor Die”. The Ni/Au metallization process advantageously provides for a Ni layer formed on bump grid arrays and an Au layer to protect the Ni layer. As Ni does not diffuse into the Al of the bump grid array contact areas, an inter-metallic layer comprised of NI/Al provides for high density layers to which solder bumps may be attached.

In a step 130 a solder mask 133 may be stenciled to provide a mask for solder paste or pre-formed solder ball reflow to form solder BGA solder bumps in a step 140. The individual die may be diced in a step 150. The common drain dual MOSFET chip scale packages are then ready for surface mounting to a PCB.

FIG. 1A illustrates diagrammatically the method of fabricating a common drain dual MOSFET 100. A thin wafer 155, such as a 7 to 8 mil wafer, may be received in a processing machine. The wafer may have disposed thereon a plurality of common drain dual MOSFET devices 160. Common drain dual MOSFET 160 may include a back drain metal surface 163 insulated from damage with a cured dielectric material coating 165. Cured dielectric material coating 165 may further provide mechanical strength to common drain dual MOSFET 160.

Under bump metallization may include the metallization of bump grid arrays 167 with Ni/Au. A solder mask 170 may be stenciled to provide the mask for solder paste or pre-formed solder ball reflow to form solder BGA solder bumps 173. The wafer 155 may then be diced to form the plurality of common drain dual MOSFET chip scale packages 210.

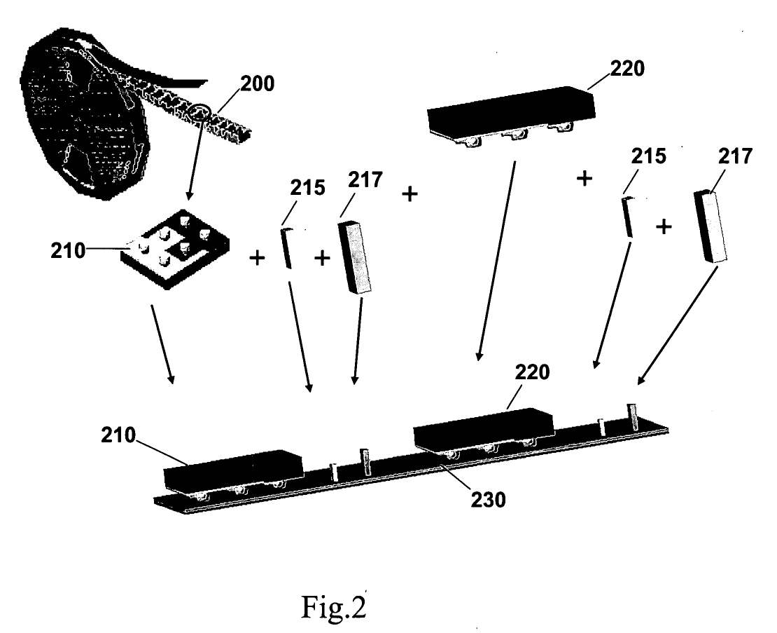

As shown schematically in FIG. 2, a tape automated bonding attachment process may include a tape 200 to which are attached a plurality of electronic components including the common drain dual MOSFET chip scale package 210, discrete passive components including resistors 215 and capacitors 217, and a control IC chip scale package 220. The tape automated bonding attachment process may be utilized to attach the common drain dual MOSFET chip scale package 210, the discreet passive components 215 and 217 and the control IC chip scale package 220 to a PCB 230.

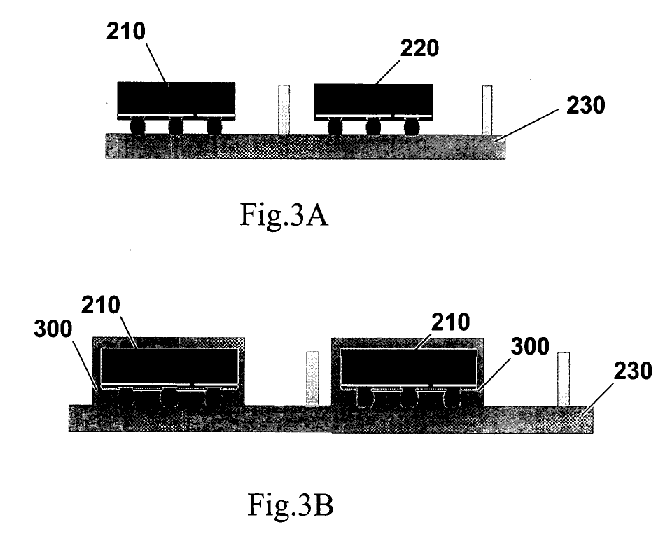

FIG. 3A shows the common drain dual MOSFET chip scale package 210 and the IC chip scale package 220 mounted to PCB 230 without molding or under fill while FIG. 3B shows the same components molded and underfilled with under fill 300. Considerations related to the use of under fill 300 include die size matching, Pb/Sn solder use, mechanical performance and device application.

The wafer level method of fabricating a plurality of common drain dual MOSFET chip scale packages of the invention provides for a process whereby common drain dual MOSFET chip scale packages may be formed from thin wafers including 7 to 8 mil wafers. The wafer level method further provides a reliable and cost effective package. The common drain dual MOSFET chip scale package in accordance with the invention has good thermal dissipation and short interconnect paths. The package of the invention also provides for low inductance and resistance as well as a compact package structure. The package is amenable to current surface mount assembly processes

It should be understood, of course, that the foregoing relates to preferred embodiments of the invention and that modifications may be made without departing from the spirit and scope of the invention as set forth in the following claims.

We claim:

1. A method of fabricating a plurality of common drain dual MOSFET chip scale packages comprising the steps of:
providing a wafer having a plurality of common drain dual MOSFET devices disposed thereon;
insulating a back drain metal surface of the wafer;
under bump metallizing ball grid array pads on each of the common drain dual MOSFET devices;
stenciling a solder mask to the wafer to expose the ball grid array pads;
reflowing solder paste to form ball grid array solder bumps; and
dicing the wafer into the plurality of chip scale packages.

2. The method of claim 1, wherein insulating the back drain metal surface comprises insulating with a cured dielectric material.

3. The method of claim 1, wherein under bump metallizing comprises Ni/Au plating.

4. A common drain dual MOSFET chip scale package comprising:
an insulating layer, the insulating layer being disposed adjacent a back drain metal surface of the common drain dual MOSFET chip.

5. The common drain dual MOSFET chip scale package of claim 4, wherein the insulating layer comprises a cured dielectric material.

6. The common drain dual MOSFET chip scale package of claim 4, further comprising Ni/Au plated under bump metallization areas.

7. The common drain dual MOSFET chip scale package of claim 6, further comprising a ball grid array of solder bumps formed on the bump metallization areas.

8. The common drain dual MOSFET chip scale package of claim 7, wherein the solder bumps are formed by reflow of solder paste.

9. The common drain dual MOSFET chip scale package of claim 7, wherein the solder bumps are formed by reflow of pre-formed solder balls.

10. A method of fabricating a plurality of common drain dual MOSFET chip scale packages comprising the steps of:
providing a wafer having a plurality of common drain dual MOSFET devices disposed thereon;
insulating a back drain metal surface of the wafer;
under bump metallizing ball grid array pads on each of the common drain dual MOSFET devices;
stenciling a solder mask to the wafer to expose the ball grid array pads;
reflowing pre-formed solder balls to form ball grid array solder bumps; and
dicing the wafer into the plurality of chip scale packages

11. The method of claim 10, wherein insulating the back drain metal surface comprises insulating with a cured dielectric material.

12. The method of claim 10, wherein under bump metallizing comprises Ni/Au plating.
